(19) United States
(12) Patent Application Publication
(10) Pub. No.: US 2016/0064587 A1
(43) Pub. Date: Mar. 3, 2016

(54) SOLAR CELL MODULE AND METHOD FOR MANUFACTURING SOLAR CELL MODULE

(71) Applicant: PANASONIC CORPORATION, Kadoma-shi, Osaka (JP)

(72) Inventor: Haruhisa HASHIMOTO, Osaka (JP)

(73) Assignee: Panasonic Intellectual Property Management Co., Ltd., Osaka (JP)

(21) Appl. No.: 14/786,954

(22) PCT Filed: Apr. 23, 2014
(86) PCT No.: PCT/JP2014/002280

§ 371 Date: Oct. 23, 2015

(30) Foreign Application Priority Data
Apr. 25, 2013 (JP) 2013-092882

(51) Int. Cl. H01L 31/05

(52) U.S. Cl. CPC H01L 31/0508

(57) ABSTRACT

A solar cell module includes a plurality of solar cell elements, a tab wiring, which connects the plurality of solar cell elements with each other, and a resin portion, which bonds the tab wiring and the surface of the solar cell element, the resin portion being nonlinearly provided on the surface of the solar cell element.

### TECHNICAL FIELD

The present invention relates to a solar cell module and a method for fabricating the solar cell modules.

### BACKGROUND TECHNOLOGY

A solar cell module has a plurality of solar cells. The plurality of solar cells have electrodes on their surfaces. The electrodes in the plurality of solar cells are connected to each other by wiring members. The wiring members are bonded, for example, such that the wiring members electrically conduct to the electrodes of the solar cells through adhesives made of resin (see Patent Document 1, for instance).

### RELATED ART DOCUMENTS

### Patent Documents

[Patent Document 1] Japanese Unexamined Patent Application Publication No. 2009-212396.

The rates of thermal expansion differ in between a solar cell and a wiring member. For this reason, when the temperature of the solar cell module changes due to its installation environment, a stress is generated between the solar cell and the wiring member with the result that the wiring member may come off.

The present invention has been made in view of foregoing circumstances, and a purpose thereof is to provide a technology for enhancing the reliability of a solar cell module.

### Means for Solving the Problems

In order to resolve the above-described problems, a solar cell module according to one embodiment of the present invention includes: a plurality of solar cell elements; a tab wiring that connects the plurality of solar cell elements with each other; and a resin portion that bonds the tab wiring and a surface of the solar cell element, the resin portion being provided, in a nonlinear shape, on the surface of the solar cell element.

Another embodiment of the present invention relates to a method for fabricating a solar cell module. The method includes: preparing a plurality of solar cell elements and a tab wiring, which connects the plurality of solar cell elements with each other; placing an adhesive nonlinearly on a surface of the solar cell element; and placing the tab wiring on the adhesive.

### Effect of the Invention

The present invention enhances the reliability of a solar cell module.

### BRIEF DESCRIPTION OF THE DRAWINGS

FIG. 1 is a cross-sectional view of a solar cell module according to an embodiment of the present invention;

FIG. 2 is an external view of light-receiving surfaces of solar cell elements according to an embodiment of the present invention;

FIG. 3 is an external view of back surfaces of solar cell elements according to an embodiment of the present invention;

FIG. 4 is an external view of a resin portion provided on a light-receiving surface according to an embodiment of the present invention;

FIG. 5 is a cross-sectional view showing a structure of a resin portion on a light-receiving surface according to an embodiment of the present invention;

FIG. 6 is a cross-sectional view showing a structure of a resin portion on a light-receiving surface according to an embodiment of the present invention;

FIG. 7 is a cross-sectional view showing a structure of a resin portion on a light-receiving surface according to an embodiment of the present invention;

FIG. 8 is an external view of a resin portion provided on a back surface according to an embodiment of the present invention;

FIG. 9 is an external view of an adhesive placed on a light-receiving surface according to an embodiment of the present invention;

FIG. 10 shows a printing plate used for the placement of an adhesive according to an embodiment of the present invention;

FIG. 11 shows a tab wiring bonded to a light-receiving surface according to an embodiment of the present invention;

FIG. 12 is an external view of an adhesive placed on a back surface according to an embodiment of the present invention;

FIG. 13 shows a tab wiring bonded to a back surface according to an embodiment of the present invention;

FIGS. 14A to 14C schematically show advantageous effects achieved by an adhesive according to an embodiment of the present invention; and

FIG. 15 is an external view of an adhesive applied on a back surface according to a modification.

### MODES FOR CARRYING OUT THE INVENTION

Hereinbelow, the invention will be described in detail through exemplary embodiments with reference to the accompanying drawings. Note that in all of the Figures the same reference numerals are given to the same components and the repeated description thereof is omitted as appropriate.

The present invention will be outlined before it is explained in detail. The present embodiments relates to a technology used to bond a tab wiring to surfaces of solar cell elements. Here, the tab wiring is a wiring or wire(s) by which to connect a plurality of solar cell elements constituting a solar cell module. In recent years, there are cases where, for the purpose of reducing the overall cost, a resin adhesive is applied on the surfaces of the solar cell elements and then the tab wiring is placed thereon so as to bond the tab wiring thereon. In such a case, providing the resin adhesive on the surface of the solar cell element covers a part of the surface thereof and thereby reduces a light receiving area; thus it is suitable that the resin adhesive is provided in an elongated manner (in a long-and-thin manner). At the same time, when the region where the resin adhesive is thinly arranged and if the position of the tab wiring arranged is shifted or displaced in a short direction, the tab wiring cannot be reliably bonded. For this reason, in the present embodiments, the resin adhesive with which the tab wiring is bonded is provided in a nonlinear shape. With this configuration and arrangement, the tab wiring is reliably bonded in the event the arrangement of the tab wiring is shifted or displaced, thereby enhancing the reliability of the solar cell module.

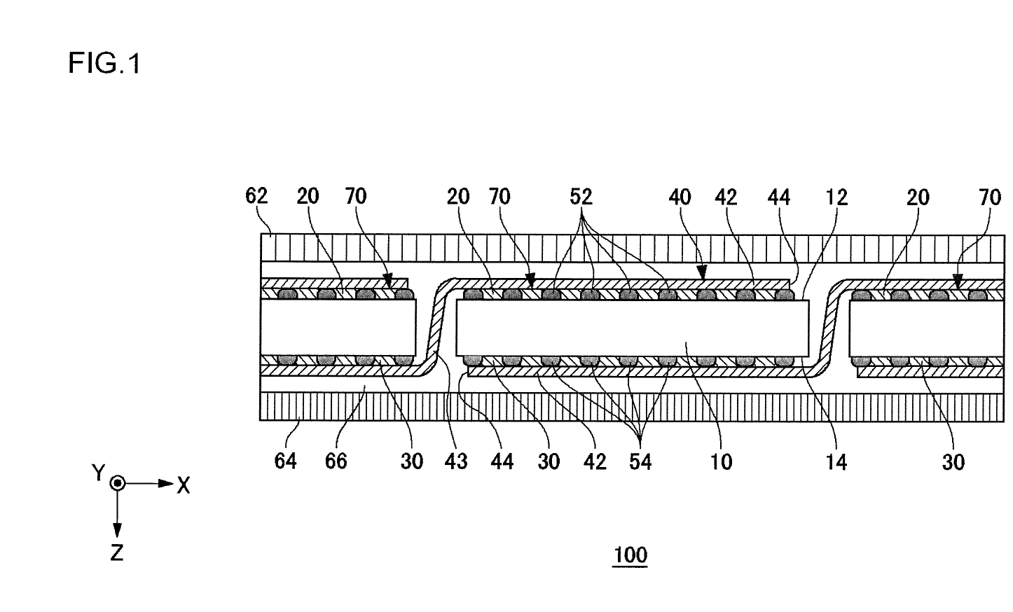

FIG. 1 is a cross-sectional view of a solar cell module 100 according to an embodiment of the present invention.

The solar cell module 100 according to the present embodiment includes a plurality of solar cell elements 70, a tab wiring 40, which interconnects the adjacent solar cell elements 70, resin portions 52 and 54, a protective substrate 62, a back sheet 64, and a sealing layer 66. A detailed description is hereunder given of these components in order.

Each solar cell element 70 includes a power generation layer 10, first electrodes 20, and second electrodes 30.

The power generation layer 10 is a layer that absorbs the incident light and generates a photovoltaic power, and has a substrate formed of a semiconductor material like crystalline silicon, gallium arsenide (GaAs) or indium phosphide (InP), for instance. In the present embodiment, the structure of the power generation layer 10 is not limited to any particular one but has a heterojunction of an n-type single-crystal silicon substrate and an amorphous silicon. The power generation layer 10 is constructed on a light-receiving surface side of the n-type single-crystal silicon substrate such that, for example, an i-type amorphous silicon layer, a p-type amorphous silicon layer doped with boron (B) or the like, and a transparent conductive layer formed of a translucent conductive oxide are stacked in this order. Also, the power generation layer 10 is constructed on a back surface of the substrate such that an i-type amorphous silicon layer, an n-type amorphous silicon layer doped with phosphorus (P) or the like, and a transparent conductive layer are stacked in this order.

The power generation layer 10 has a light-receiving surface, which is one of surfaces of the solar cell element 70, and a back surface 14, which is one of surfaces thereof and which faces the light-receiving surface 12 across the power generation layer 10. Here, the light-receiving surface means a main surface through which light (sunlight) mainly enters and is a surface through which the majority of light incident on the solar cell element 70 enters.

The first electrodes 20 and the second electrodes 30 are electrodes provided on the surfaces of the solar cell element 70 and are electrodes that extract the electric power generated by the power generation layer 10 to an outside. The first electrodes 20 are provided on the light-receiving surface 12, and the second electrodes 30 are provided on the back surface 14. The first electrodes 20 and the second electrodes 30 are conductive materials containing a metal such as silver (Ag), copper (Cu) or the like. The first electrodes 20 and the second electrodes 30 may each further contain an electrolytic plating layer such as copper (Cu) or tin (Sn). However, this should not be considered as limiting and, for example, those may be formed of other metals, such as gold (Au), other conductive materials, or a combination thereof.

The tab wiring 40 is bonded to the surfaces of the solar cell elements 70 by using the resin portions 52 so that the tab wiring 40 electrically conducts to the first electrodes 20. Also, the tab wiring 40 is bonded to the surfaces thereof by using the resin portions 54 so that the tab wiring 40 electrically conducts to the second electrodes 20. The tab wiring 40 is a long and thin metallic foil; the tab wiring 40 as used herein is, for example, copper foil coated with silver or aluminum foil. The tab wiring 40 extends in a first direction (x direction) where a plurality of solar cell elements 70 are arranged, and connects to the first electrodes 20 of one of adjacent solar cell elements 70 in the x direction and the second electrodes 30 of the other thereof.

The tab wiring 40 includes an extending portion 42, a bent portion 43, and a tip end portion 44.

The extending portion 42 extends along the light-receiving surface 12 or the back surface 14 in the x direction. The extending portion 42 is bonded to the light-receiving surface 12 by way of the resin portions 52 and is bonded to the back surface 14 by way of the resin portions 54. More specifically, the extending portion 42 is placed on the first electrodes 20 or the second electrodes 30 and is bonded in such a manner as to electrically conduct to the electrodes; at this time, the extending portion 42 is bonded in a state of being in direct contact with part of the electrodes.

The tip end portion 44 is provided on the light-receiving surface 12 or the back surface 14, and is arranged in a region close to the outer periphery of the solar cell element 70.

The bent portion 43 has a stepped portion equivalent to the thickness of the solar cell element 70. Provision of the bent portion 43 allows the tab wiring 40 to connect the light-receiving surface 12 of one of the solar cell elements 70 and the back surface 14 of the other thereof in a state where the light-receiving surface 12 and the back surface 14 in each of a plurality of solar cell elements are placed coplanar with each other.

The protective substrate 62 and the back sheet 64 protect the solar cell elements 70 from being directly exposed to the outside environment. The protective substrate 62 provided on a light-receiving surface 12 side transmits the light, having a wavelength band, which is absorbed by the solar cell elements 70 for the generation of the electric power. The protective substrate 62 is a glass substrate, for instance. The back sheet 64 provided on the back surface 14 is a resin substrate, such as EVA or polyimide, or is the same glass substrate as the protective substrate 62.

The sealing layer 66 is formed of a resin material such as ethylene-vinyl acetate copolymer (EVA), polyvinyl butyral (PVB) or polyimide. This not only prevents the entry and the like of moisture into the solar cell elements 70 but also enhances the strength of the solar cell module 100 as a whole. In order for the solar cell elements 70 to absorb an increased amount of the light entering from a protective substrate 62 side, a metallic foil or the like may be provided between the back sheet 64 and the sealing layer 66. In such a case, the light, which transmits the solar cell elements 70 and has reached the back sheet 64, may be reflected to the solar cell elements 70.

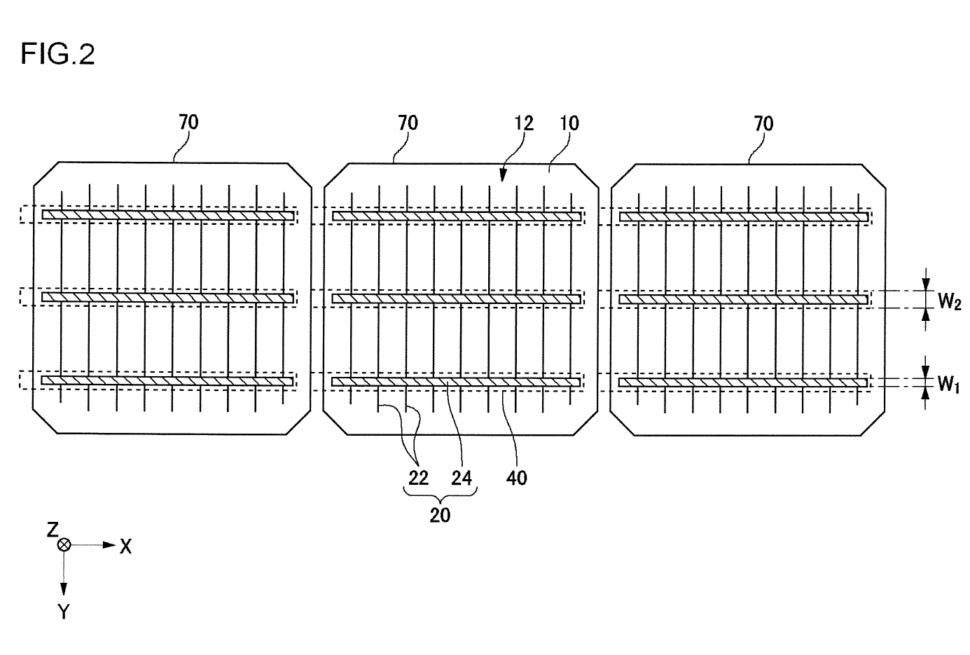

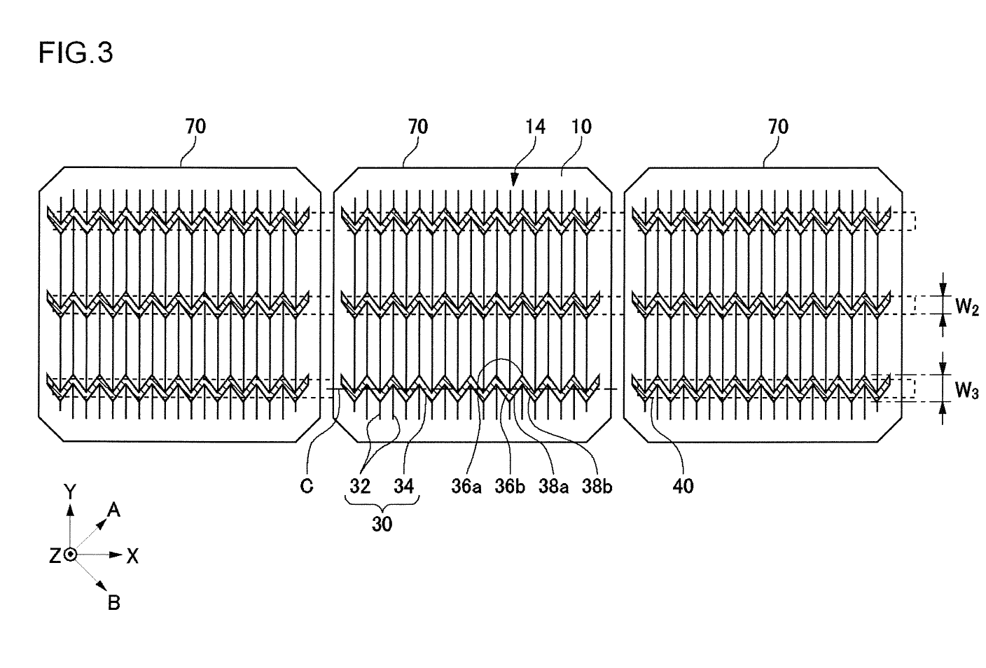

A detailed description is now given of structures of the first electrode 20 and the second electrode 30 with reference to FIGS. 2 and 3.

FIG. 2 is an external view of the light-receiving surfaces 12 of the solar cell elements 70. In FIG. 2, a region where the tab wiring 40 is arranged is indicated and surrounded by a broken line.

The first electrodes 20 include three bus-bar electrodes 24, which extend in parallel with each other in the x direction, and a plurality of finger electrodes 22, which extend in a second direction (y direction) perpendicular to the bus-bar electrodes 24. Since the finger electrode 22 is an electrode formed on the light-receiving surface 12, it is suitable that the finger electrode 22 be formed to have a narrow shape in order not to block the light incident on the power generation layer 10. Also, it is suitable that the finger electrodes 22 be arranged at predetermined intervals in order that the power generated can be efficiently collected.

The bus-bar electrode 24 connects the plurality of finger electrodes 22 with each other and extends linearly in the x direction. It is suitable that the bus-bar electrode 24 is not only formed to a degree such that the light entering the power generation layer 10 is not blocked but also formed to have a certain thickness such that the electric power collected from the plurality of finger electrodes 22 is efficiently delivered. In the present embodiment, the bus-bar electrode 24 in the y direction is formed such that a width w₁ thereof is narrower than a width w₂ of the tab wiring 40.

FIG. 3 is an external view of the back surfaces 14 of the solar cell elements 70. In FIG. 3, too, a region where the tab wiring 40 is arranged is indicated and surrounded by a broken line but, for convenience, the description of the region where the tab wiring 40 is arranged is omitted here.

Similar to the first electrodes 20, the second electrodes 30 also include three bus-bar electrodes 34, which extend in parallel with each other in the x direction, and a plurality of finger electrodes 32, which extend in the y direction perpendicular to the bus-bar electrodes 34. On the other hand, the second electrodes 30 differ from the first electrodes 20 in that the second electrode 30 has a nonlinearly-formed bus-bar electrode 34. More specifically, the bus-bar electrode 34 is formed in a zigzag shape. Since the back surface 14 is not the main surface through which the sunlight mainly enters, the finger electrodes 32 on the back surface 14 are provided such that the number of finger electrodes 32 on the back surface 14 is larger than the number of finger electrodes 22 on the light-receiving surface 12. Thus, the current collecting efficiency of the finger electrodes 32 is higher than that of the finger electrodes 22.

The bus-bar electrode 34 on the back surface 14 is so formed in a zigzag shape as to repeatedly and continuously lie across a central line C. Here, the central line C extends in the x direction by connecting the center positions of a zigzag in the y direction that is the short direction of the tab wiring 40. In other words, the bus-bar electrode 34 makes a zigzag movement continuously between upper vertices and lower vertices in the short direction of the bus-bar electrode 34 and thereby extends in the x direction that is a longitudinal direction of the bus-bar electrode 34. In the present embodiment, the bus-bar electrode 34 in the y direction is formed such that a width w₃ thereof is wider than a width w₂ of the tab wiring 40.

Each bus-bar electrode 34 includes a plurality of first vertices 36a, a plurality of second vertices 36b, a plurality of first connection electrodes 38a, and a plurality of second connection electrodes 38b.

The first vertex 36a and the second vertex 36b (hereinafter generically referred to as “vertex 36” or “vertices 36” also) are the bent portions where the zigzag-shaped bus-bar electrode 34 changes the extending direction thereof, and are provided in positions separated away, respectively, from the central line C of the bus-bar electrode 34. The first vertex 36a is provided in a position separated away from the central line C (namely, with the central line C being set as a reference position) in a positive y direction (an upward direction on the sheet surface of FIG. 3); the second vertex 36b is provided in a position separated away from the central line C in a negative y direction (a downward direction on the sheet surface of FIG. 3). The first vertex 36a and the second vertex 36b, which are located adjacent to each other, are connected by the first connection electrode 38a or the second connection electrode 38b. In the present embodiment, the vertices 36 are provided in positions where the finger electrodes 32 are provided. In a modification, the vertices 36 may be provided in positions different from those of the finger electrodes 32.

The first connection electrode 38a and the second connection electrode 38b extend in directions obliquely intersecting with the central line C, and thereby connect the first vertex 36a and the second vertex 36b, which are located adjacent to each other. The first connection electrode 38a extends from the second vertex 36b toward the first vertex 36a in a direction between the positive x direction and the positive y direction (namely, a right obliquely upward direction A on the sheet surface of FIG. 3). On the other hand, the second connection electrode 38b extends from the first vertex 36a toward the second vertex 36b in a direction between the positive x direction and the negative y direction (namely, a right obliquely downward direction B on the sheet surface of FIG. 3). The first connection electrode 38a, which extends in the right obliquely upward direction A), and the second connection electrode 38b, which extends in the right obliquely downward direction B), are provided alternately to each other. Thereby, the bus-bar electrode 34 is formed in the zigzag shape.

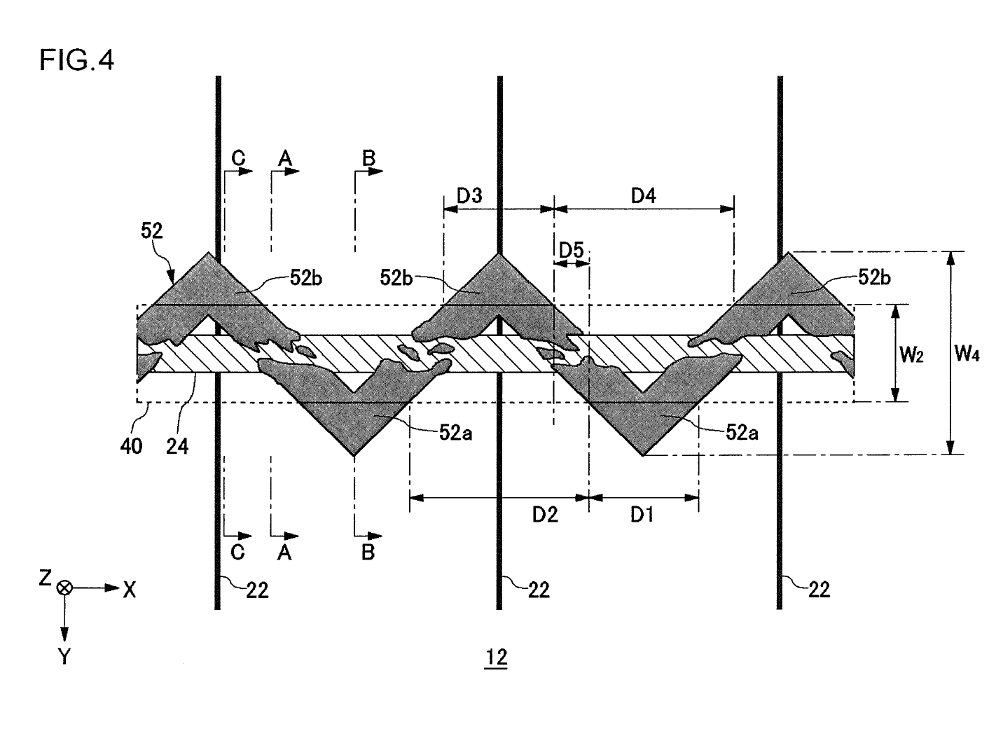

A detailed description is now given of the structure of the resin portion 52 provided on the light-receiving surface 12, with reference to FIG. 4 to FIG. 7.

FIG. 4 is an external view of the resin portion 52 provided on the light-receiving surface 12. In FIG. 4, too, the description of the tab wiring 40 provided on the light-receiving surface 12 is omitted, and the region where the tab wiring 40 is arranged is indicated and surrounded by a broken line.

The resin portion 52, which is provided on the light-receiving surface 12, bonds the light receiving surface 12 and the tab wiring 40 extending above the light-receiving surface 12. The resin portion 52 is an adhesion layer where a resin adhesive is hardened, and uses, for example, a thermosetting resin material such as epoxy resin, acrylic resin or urethane resin. Although, in the present embodiment, an insulating resin material is used as the resin portion 52, it may have electrical conductivity by, for example, dispersing conductive particles or the like into the resin material.

The resin portion 52 is provided, in a nonlinear shape, along the bus-bar electrode 24 extending in the x direction. More specifically, the resin portion 52 is formed in a zigzag shape such that the resin portion 52 repeatedly and continuously lies across the bus-bar electrode 24, which is located in the center position in the y direction that is the short direction of the tab wiring 40, while making a zigzag movement continuously between upper vertices and lower vertices in the short direction of the bus-bar electrode 24. The resin portion 52 is provided such that a width w₄ thereof in the short direction is wider than a width w₂ of the tab wiring 40.

The resin portion 52 includes first fillets 52a and second fillets 52b.

The first fillet 52a is provided on one side of the short direction of the tab wiring 40 (namely, a positive y direction side of the tab wiring 40) in a protruding manner. The first fillets 52a are provided such that the first fillets 52a are discontinuously provided in the longitudinal direction of the tab wiring 40. On the positive y direction side of the tab wiring 40, a first region D1, where the first fillet 52a is formed, and a second region D2, where no first fillet 52a is formed, are provided alternately to each other.

The second fillet 52b is provided on the other side of the short direction of the tab wiring 40 (namely, a negative y direction side of the tab wiring 40) in a protruding manner. The second fillets 52b are provided such that the second fillets 52b are discontinuously provided in the longitudinal direction of the tab wiring 40. On the negative y direction side of the tab wiring 40, a third region D3, where the second fillet 52a is formed, and a fourth region D4, where no second fillet 52b is formed, are provided alternately to each other.

The first region D1, where the first fillet 52a is formed, and the third region D3, where the second fillet 52b is formed, are provided such that the first region D1 and the third region D3 do not overlap with each other in the longitudinal direction of the tab wiring 40. Thereby, a fifth region D5, where neither the first fillet 52a nor the second fillet 52b is provided, is provided in between the first region D1 and the third region D3. In a modification where no fifth region is provided, the first fillet 52a and the second fillet 52b may be provided in between the first region D1 and the third region D3.

FIG. 5 is a cross-sectional view showing a structure of the resin portion 52 on the light-receiving surface 12, and is a cross-sectional view taken along the line A-A of FIG. 4. FIG. 5 is a cross-sectional view of the fifth region D5 where no first fillet 52 or second fillet 52 is formed.

The resin portion 52 is provided around the bus-bar electrode 24 in the fifth region D5 and is provided such that a thickness h of the resin portion 52 from the light-receiving surface 12 is equal to the thickness of the bus-bar electrode 24. The resin portion 52 bonds the tab wiring 40 and the light-receiving surface 12 by having the resin portion 52 come in contact with at least part of an undersurface 40a of the tab wiring 40. Also, the undersurface 40a of the tab wiring 40 is in direct contact with the bus-bar electrode 24 so as to electrically conduct thereto.

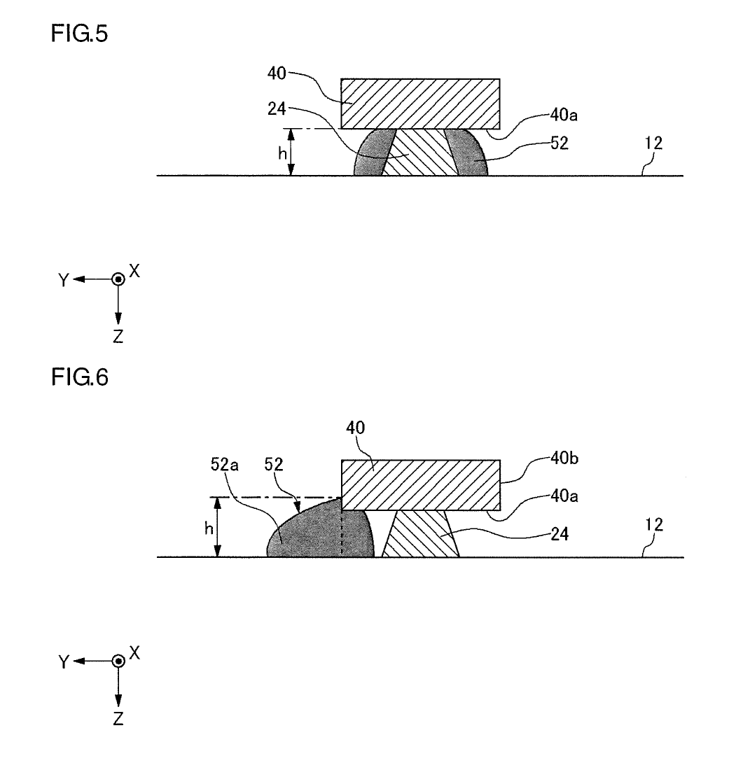

FIG. 6 is a cross-sectional view showing a structure of the resin portion 52 on the light-receiving surface 12, and is a cross-sectional view taken along the line B-B of FIG. 4. FIG. 6 is a cross-sectional view of the first region D1 where the first fillet 52a is formed.

The resin portion 52 is provided in the positive y direction of the bus-bar electrode 24 on the first region D1. The resin portion 52 bonds the tab wiring 40 and the light-receiving surface 12 by having the resin portion 52 come in contact with at least part of an undersurface 40a of the tab wiring 40. Also, the undersurface 40a of the tab wiring 40 is in direct contact with the bus-bar electrode 24 so as to electrically conduct thereto.

The first fillet 52a is formed on the positive y direction side of the tab wiring 40 and is provided such that the thickness h of the first fillet 52a from the light-receiving surface 12 is larger than the thickness of the bus-bar electrode 24. The first fillet 52a bonds the tab wiring 40 and the light-receiving surface 12 by having the first fillet 52a come in contact with at least part of a lateral surface 40b of the tab wiring 40.

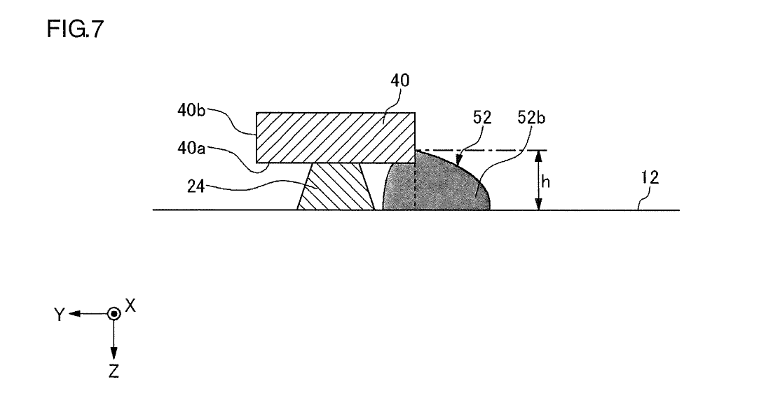

FIG. 7 is a cross-sectional view showing a structure of the resin portion 52 on the light-receiving surface 12, and is a cross-sectional view taken along the line C-C of FIG. 4. FIG. 7 is a cross-sectional view of the third region D3 where the second fillet 52b is formed.

The resin portion 52 is provided on the negative y direction side of the bus-bar electrode 24 in the third region D3. The resin portion 52 bonds the tab wiring 40 and the light-receiving surface 12 by having the resin portion 52 come in contact with at least part of the undersurface 40a of the tab wiring 40. Also, the undersurface 40a of the tab wiring 40 is in direct contact with the bus-bar electrode 24 so as to electrically conduct thereto.

The second fillet 52b is formed on the negative y direction side of the tab wiring 40 and is provided such that the thickness h of the second fillet 52b from the light-receiving surface 12 is larger than the thickness of the bus-bar electrode 24. The second fillet 52b bonds the tab wiring 40 and the light-receiving surface 12 by having the second fillet 52b come in contact with at least part of the lateral surface 40b of the tab wiring 40.

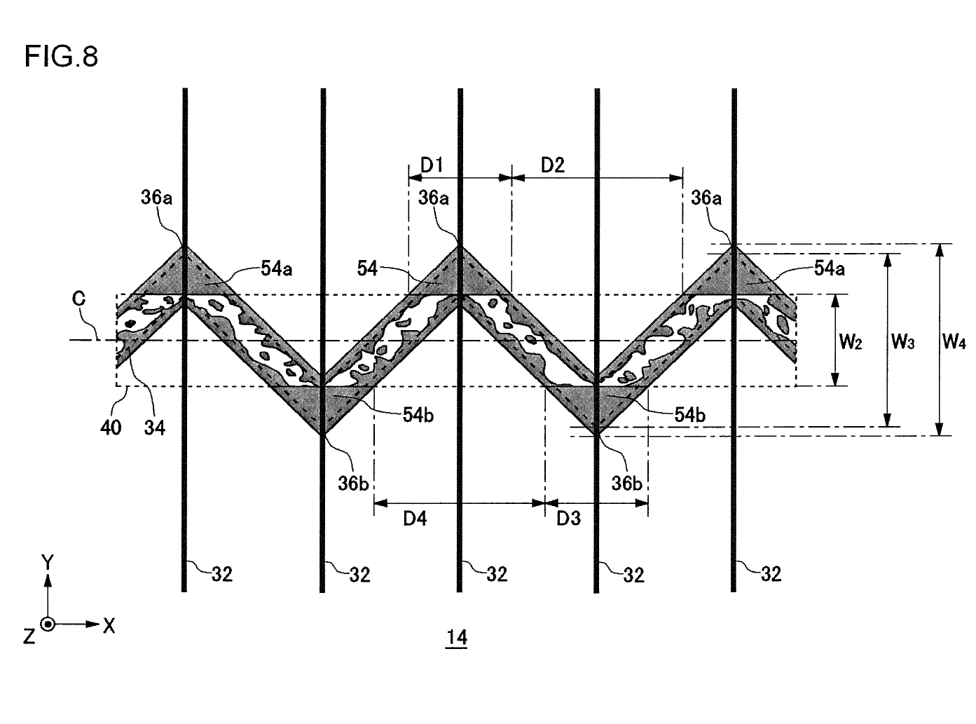

A detailed description is now given of the structure of the resin portion 54 provided on the back surface 14, with reference to FIG. 8.

FIG. 8 is an external view of the resin portion 54 provided on the back surface 14. Similar to FIG. 4, in FIG. 8 the description of the tab wiring 40 provided on the back surface 14 is omitted, and the region where the tab wiring 40 is arranged is indicated and surrounded by a broken line.

The resin portion 54, which is provided on the back surface 14, bonds the back surface 14 of the solar cell element 70 and the tab wiring 40 extending above the resin portion 54. Similar to the resin portion 52, the resin portion 54 is an adhesion layer where a resin adhesive is hardened, and uses, for example, a thermosetting resin material such as epoxy resin, acrylic resin or urethane resin.

The resin portion 54 is provided, in a nonlinear shape, along the central line C of the bus-bar electrode 34 extending in a zigzag shape. More specifically, the resin portion 54 extends in the longitudinal direction such that the resin portion 54 extends in the longitudinal direction according to the zigzag shape of the bus-bar electrode 34, while making a continuous movement between upper vertices and lower vertices in the short direction of the bus-bar electrode 34. The resin portion 54 is provided such that the width w₄ thereof in the short direction is slightly wider than the width w₃ of the bus-bar electrode 34 in the short direction.

The resin portion 54 is provided around the bus-bar electrode 34 as well and is provided such that the thickness of the resin portion 54 from the back surface 14 is equal to the thickness of the bus-bar electrode 34. The resin portion 54 bonds the tab wiring 40 and the back surface 14 of the solar cell element 70 by having the resin portion 54 come in contact with at least part of an undersurface of the tab wiring 40. The tab wiring 40 is in direct contact with the bus-bar electrode 34 so as to electrically conduct thereto.

The resin portion 54 includes first fillets 54a and second fillets 54b.

The first fillet 54a is provided on one side of the short direction of the tab wiring 40 (namely, the positive y direction side of the tab wiring 40) in a protruding manner, and is so provided as to cover the first vertex 36a. The first fillets 54a are provided such that the first fillets 54a are discontinuously provided in the longitudinal direction of the tab wiring 40. On the positive y direction side of the tab wiring 40, a first region D1, where the first fillet 54a is formed, and a second region D2, where no first fillet 54a is formed, are provided alternately to each other. The first fillet 54a is provided such that the thickness thereof from the back surface 14 is larger than the thickness of the bus-bar electrode 34. The first fillet 54a bonds the tab wiring 40 and the back surface 14 by having the first fillet 54a come in contact with at least part of a lateral surface of the tab wiring 40.

The second fillet 54b is provided on the other side of the short direction of the tab wiring 40 (namely, the negative y direction side of the tab wiring 40) in a protruding manner, and is so provided as to cover the second vertex 36b. The second fillets 54b are provided such that the second fillets 54b are discontinuously provided in the longitudinal direction of the tab wiring 40. On the negative y direction side of the tab wiring 40, a third region D3, where the second fillet 54b is formed, and a fourth region D4, where no second fillet 54b is formed, are provided alternately to each other. The second fillet 54b is provided such that the thickness thereof from the back surface 14 is larger than the thickness of the bus-bar electrode 34. The second fillet 54b bonds the tab wiring 40 and the back surface 14 by having the second fillet 54b come in contact with at least part of a lateral surface of the tab wiring 40.

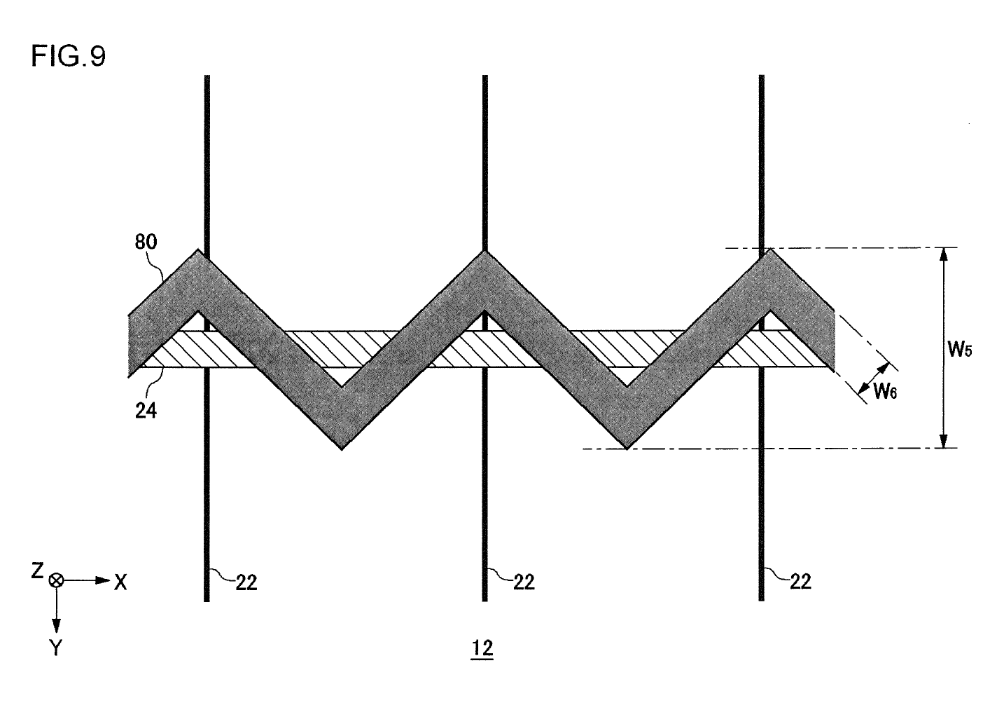

A description is now given of an exemplary method for fabricating a solar cell module 100 with reference to FIG. 9 to FIG. 13. A detailed description is first given of a process of bonding a tab wiring 40 to a light-receiving surface 12 with reference to FIG. 9 to FIG. 11.

FIG. 9 is an external view of an adhesive 80 placed on the light-receiving surface 12.

A plurality of solar cell elements 70 and a tab wiring are first prepared, and the adhesive 80 used to bond the tab wiring is applied to the surface of the solar cell elements. The adhesive 80 is a pasty resin adhesive and has a thermosetting property. For example, an epoxy resin to which a curing agent has been added is mixed with a solid component, and thereby a pasty resin before curing can be used.

The adhesive 80 is arranged on the light-receiving surface 12, in a nonlinear shape, along the longitudinal direction of the bus-bar electrode 24. More specifically, the adhesive 80 is arranged in a zigzag shape such that the adhesive 80 repeatedly and continuously lies across the bus-bar electrode 24, which is located in the center position in the y direction that is the short direction. The adhesive 80 in the y direction is provided such that a width w₅ thereof is wider than the width of the tab wiring. Hence, in the event that the position, where the tab wiring is arranged, is shifted or displaced in the y direction when the tab wiring is placed from above the adhesive 80, the tab wiring can be bonded suitably as long as the shifted amount is within a predetermined range.

Also, the adhesive 80 is provided such that a width w₆ thereof is narrower than the width w₅ in the y direction and the width of the tab wiring. For example, the adhesive 80 is provided such that the width w₆ thereof is approximately equal to the width of the tab wiring. This not only ensures a certain adhesion strength but also prevents the light receiving area from becoming narrow as a result of the widening of the fillets of the adhesive 80.

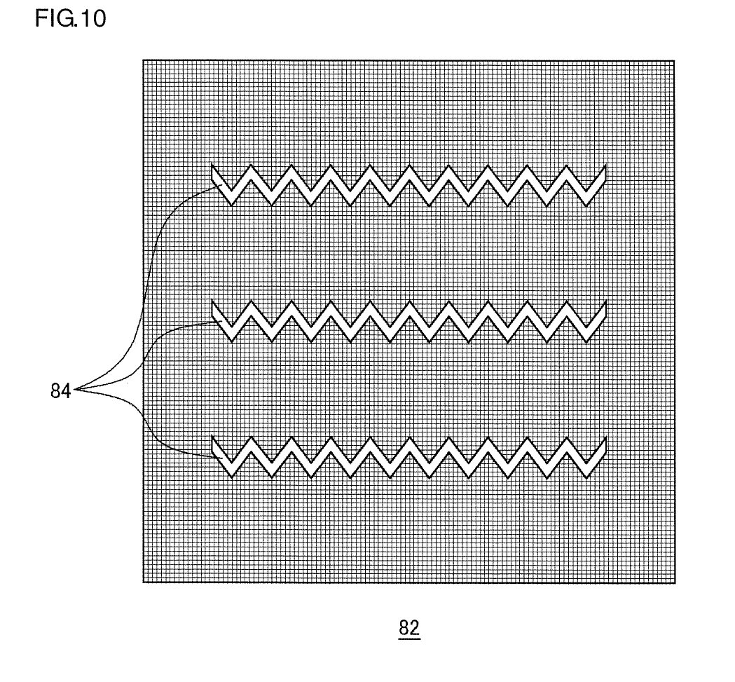

FIG. 10 shows a printing plate 82 used for the placement of the adhesive.

The printing plate 82 has patterns 84 corresponding to the shapes of the nonlinearly-shaped resin portions. Three patterns 84, which are each formed in a zigzag shape, corresponding to the positions of the bus-bar electrodes provided on the surface are provided in the printing plate 82. By printing the patterns 84 via the printing plate 82, the adhesive 80 is so arranged as to extend in a zigzag shape on the light-receiving surface 12. The offset printing is used as a printing method. If, for example, the printing is to be carried out by using the intaglio offset printing, a printing plate having a recessed section may be used as the pattern 84. Besides, the printing may be done by using the screen printing. In this case, the adhesive may be applied (overpainted) a plurality of times in accordance with the thickness of the adhesive to be applied.

Note that the adhesive 80 may be applied using a discharge means such as a dispenser. In this case, a tip part of the dispenser from which the adhesive 80 is discharged is moved in the x direction on the bus-bar electrode 24 and, at the same time, it is cyclically moved, between the vertices in the positive y direction and those in the negative y direction, from the center position in the y direction of the bus-bar electrode 24. In this manner, the adhesive 80 may be applied on the bus-bar electrode 24 in a zigzag shape.

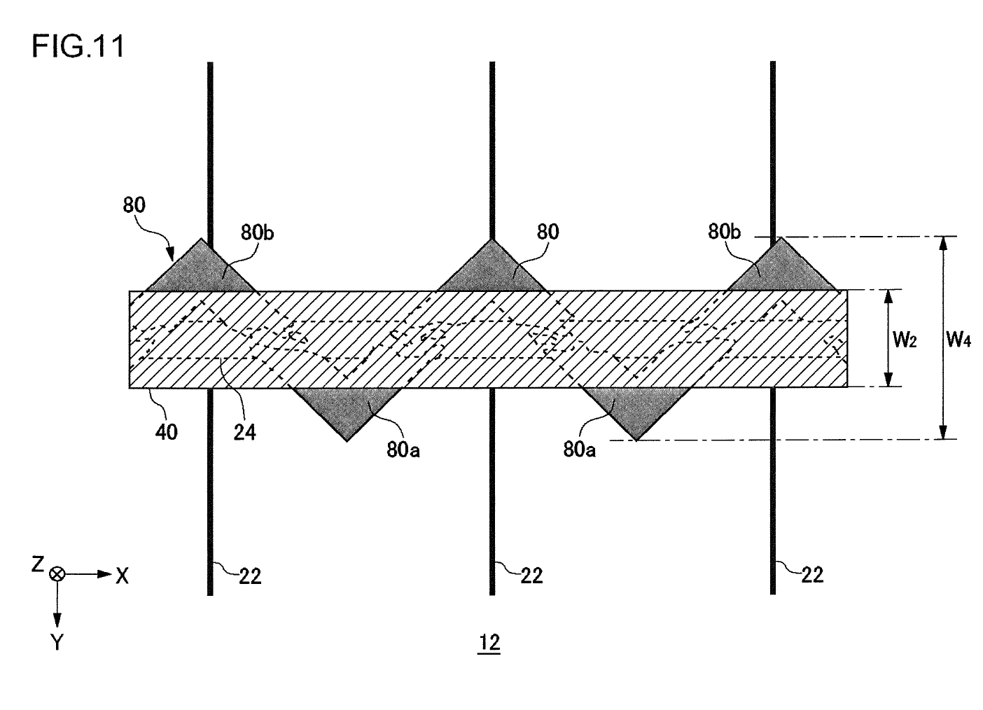

FIG. 11 shows the tab wiring 40 bonded to the light-receiving surface 12 and shows a state where the tab wiring 40 is arranged on the adhesive 80 shown in FIG. 9.

The tab wiring 40 is placed on the adhesive 80 that extends, in a zigzag shape, in a direction where the longitudinal direction of the tab wiring 40 is the x direction. Also, the tab wiring 40 is arranged such that the center position of the short direction thereof agrees with the center position of the bus-bar electrode 24. At this time, the bus-bar electrode 24 and the tab wiring 40 come in direct contact with each other so as to electrically conduct with each other. Having the center position of the tab wiring 40 agreed with (aligned to) the center position of the bus-bar electrode 24 allows the conduction of them to be in an excellent state.

When the tab wiring 40 is pressed or pressurized, part of the adhesive 80 is forced out to the periphery of the bus-bar electrode 24, the light-receiving surface 12 and the tab wiring 40 are bonded by the thus forced-out (protruding) adhesive 80. Also, part of the adhesive 80 placed on the bus-bar electrode 24 stays on between the bus-bar electrode 24 and the tab wiring 40; this directly bonds the bus-bar electrode to the tab wiring 40 and vice versa.

The adhesive 80 is arranged in a zigzag shape such that the width thereof in the short direction is wider than the width w₂ of the tab wiring 40. This forms protrusions 80a and 80b that protrude in the y direction from the tab wiring 40. As a result, the protrusions 80a and 80b, which protrude in the short direction of the tab wiring 40, are provided such that the protrusions 80a and 80b are discontinuously provided in the longitudinal direction along the tab wiring 40. Since part of the adhesive 80 spills out to the periphery when the tab wiring 40 is pressurized, the width w₄ of the adhesive 80 in the y direction after the bonding of the tab wiring 40 is slightly wider than the width w₅ of the adhesive 80 during the application of the adhesive 80 to the bus-bar electrode 24.

The tab wiring 40 is heated while the tab wiring 40 is being press-bonded. Thereby, the adhesive 80 is thermally cured so as to form the resin portion 52. Thermally curing the protrusions 80a and 80b of the adhesive 80 forms the first fillets 52a and the second fillets 52b. As a result, the resin portion 52 is provided in a zigzag shape along the tab wiring 40, and the first fillets 52a and the second fillets 52b are provided such that they are discontinuously provided in the longitudinal direction along the tab wiring 40.

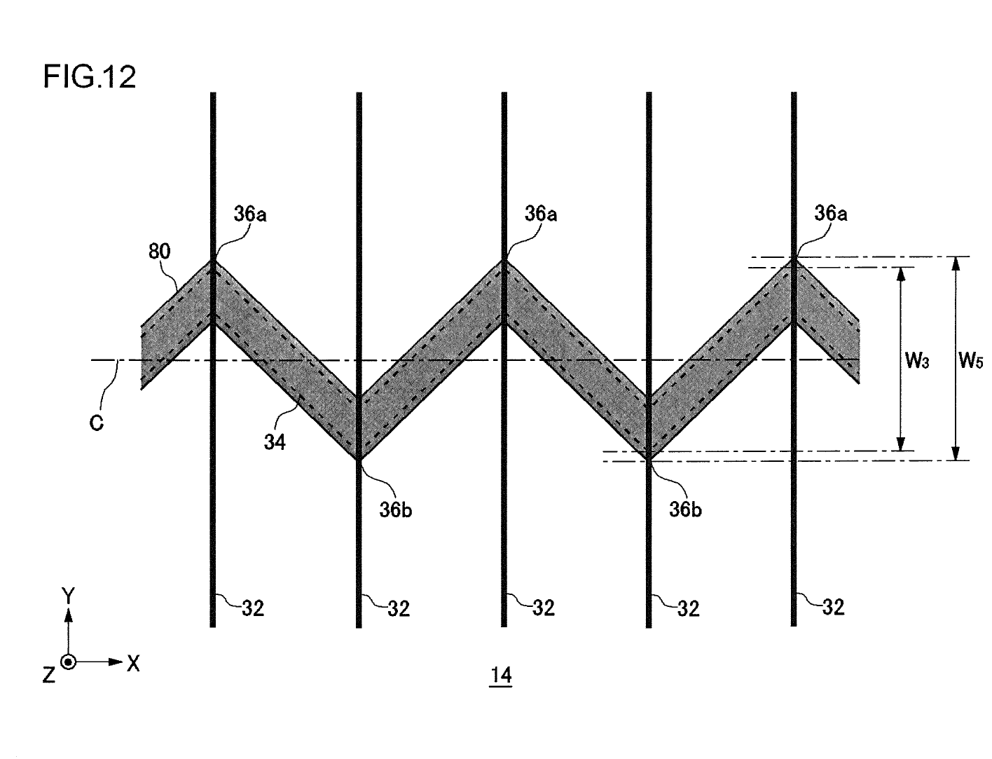

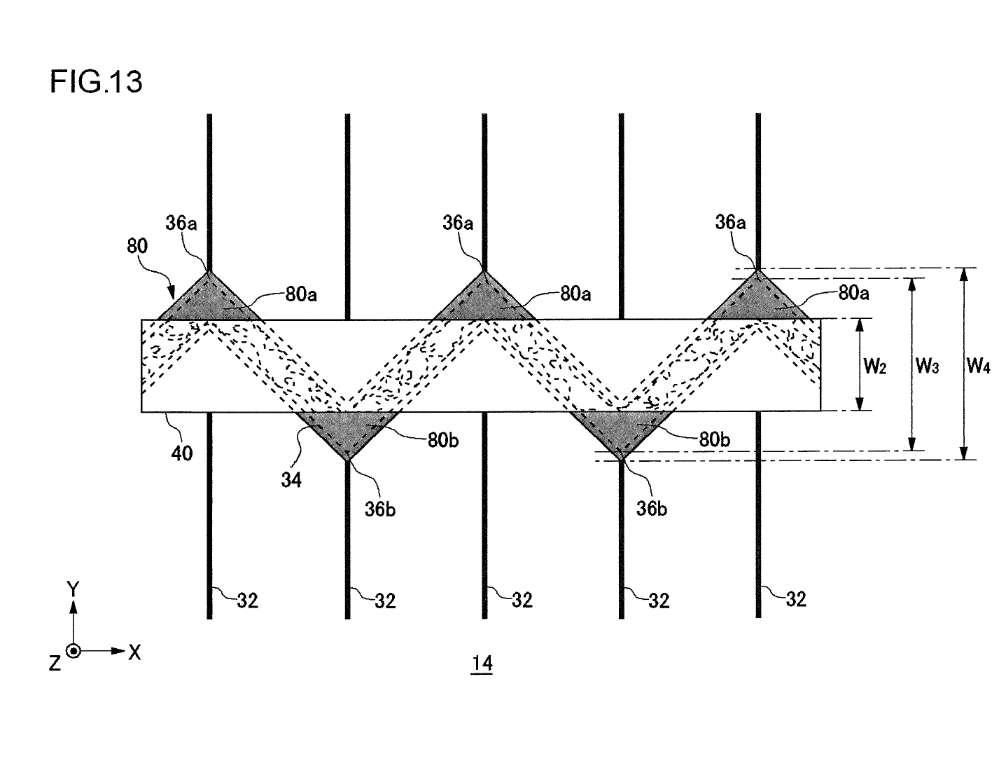

A detailed description is now given of a process of bonding the tab wiring 40 to the back surface 14 with reference to FIGS. 12 and 13. After one end of the tab wiring 40 has been bonded to the light-receiving surface 12, the other end thereof is bonded to the back surface 14.

FIG. 12 is an external view of an adhesive 80 placed on the back surface 14.

On the back surface 14, the adhesive 80 is arranged in a zigzag shape in accordance with the bus-bar electrode 34 extending in a zigzag shape. More specifically, the adhesive 80 is provided in zigzags such that the adhesive 8 connects the intersections, of the bus-bar electrode 34 and the central line C thereof, and the first vertices 36 and the second vertices of the bus-bar electrode 34. The adhesive 80 is provided such that the width w₅ thereof in the short direction is slightly wider than the width w₃ of the bus-bar electrode 34. In this manner, the adhesive 80 is brought into contact with the back surface 14 and thereby the tab wiring 40 and the back surface 14 are bonded together by the adhesive 80.

Similar to the light-receiving surface 12, the adhesive 80 is printed by using the printing plate 82 shown in FIG. 10. Note that a printing plate different from that used on a light-receiving surface 12 side may be used. For example, a printing plate may be used where the cycle and/or width of the zigzag shape of the pattern 84 differ(s) from that used on the light-receiving surface 12 side.

FIG. 13 shows a tab wiring 40 bonded to the back surface 14.

The tab wiring 40 is placed on the adhesive 80 that extends in a zigzag shape in a direction where the longitudinal direction of the tab wiring 40 is the x direction. Also, the tab wiring 40 is arranged such that the center position of the short direction thereof agrees with the central line C of the bus-bar electrode 34. At this time, the bus-bar electrode 34 and the tab wiring 40 come in direct contact with each other so as to electrically conduct with each other. When the tab wiring 40 is pressed or pressurized, part of the adhesive 80 is forced out to the periphery of the bus-bar electrode 34, the back surface 14 and the tab wiring 40 are bonded by the thus forced-out (protruding) adhesive 80.

The adhesive 80 forms the protrusions 80a and 80b that protrude in the y direction from the tab wiring 40. The width w₄ of the adhesive 80 in the y direction after the bonding of the tab wiring 40 is broadened because the adhesive 80 in the y direction is pushed out by the tab wiring 40. Hence, the width w₄ thereof is enlarged wider than the width w₅ of the adhesive 80 during the application of the adhesive 80 to the bus-bar electrode 24. Also, the protrusions 80a and 80b, which protrude in the short direction of the tab wiring 40, are provided such that the protrusions 80a and 80b are discontinuously provided in the longitudinal direction along the tab wiring 40.

The tab wiring 40 is heated while the tab wiring 40 is being press-bonded. Thereby, the adhesive 80 is thermally cured so as to form the resin portion 54. Thermally curing the protrusions 80a and 80b of the adhesive 80 forms the first fillets 52a and the second fillets 52b. As a result, the resin portion 54 is provided in a zigzag shape along the tab wiring 40, and the first fillets 52a and the second fillets 52b are provided such that they are discontinuously provided in the longitudinal direction along the tab wiring 40.

Finally, a plurality of solar cell elements 70, where the tab wirings 40 are connected, are sealed off. A resin sheet, which constitutes a part of the sealing layer 66, and the protective substrate 62 are arranged on the light-receiving surface 12 side of the plurality of solar cell elements 70, where the tab wirings 40 are connected. Also, a resin sheet, which constitutes a part of the sealing layer 66, and the back sheet 64 are arranged on the back surface 14 side thereof. Then, the solar cell elements 70 are heated and press-bonded while the solar cell elements 70 are being held between the protective substrate 62 and the back sheet 64. Thereby, the resin sheets on the light-receiving surface 12 side and the back surface 14 side are fused together so as to form the sealing layer 66. This forms a solar cell module 100.

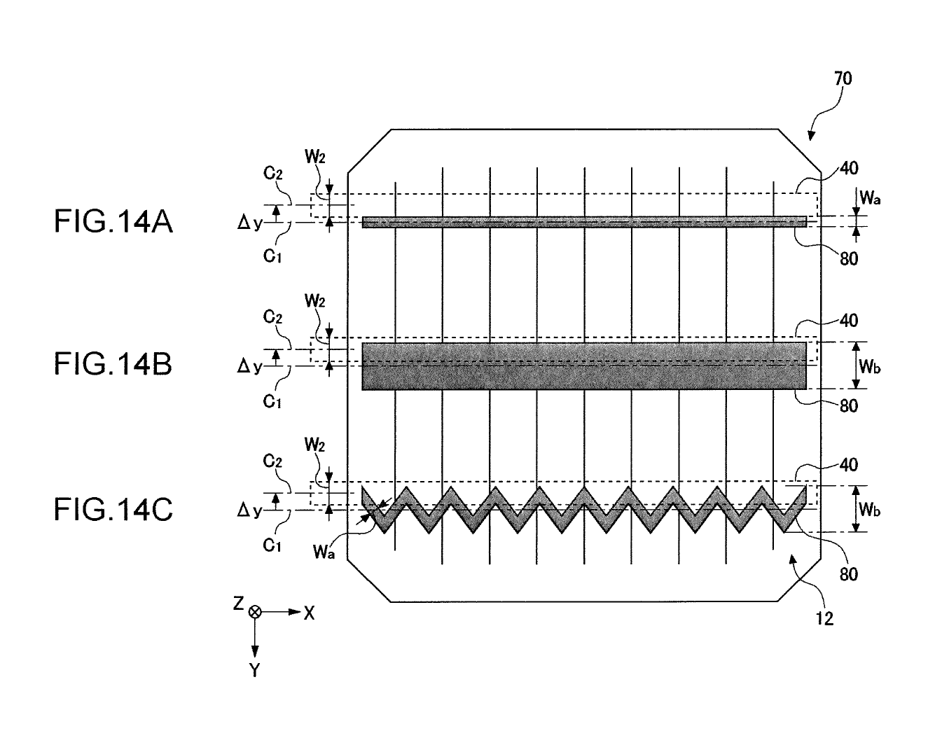

A description is now given of advantageous effects achieved by the solar cell module 100, according to the present embodiment, with reference to FIGS. 14A to 14C.

FIGS. 14A to 14C schematically show the advantageous effects achieved by the adhesive 80.

FIGS. 14A to 14C each shows how the position of the tab wiring 40 in the short direction is shifted or displaced relative to a position where the adhesive 80 is provided. In each case of FIG. 14A to FIG. 14C, the tab wiring 40 is arranged such that a central line C₂ of the tab wiring 40 is in a position shifted away from a central line C₁ of the adhesive 80 by Δy. In order to preferably bond the tab wiring 40, the arrangement thereof is suitably made such that the central line C₁ of the adhesive 80 agrees with the central line C₂ of the tab wiring 40. However, the tab wiring 40 may possibly be displaced in the short direction depending on the positioning accuracy in a bonding process of the tab wiring 40. A problem to be resolved by the present embodiment is hereunder presented using comparative examples shown in FIGS. 14A and 14B, and the advantageous effects achieved thereby are discussed below using FIG. 14C.

FIG. 14A shows an adhesive 80 according to a first comparative example. The adhesive 80 according to the first comparative example extends linearly in the longitudinal direction and is provided such that a width wₐ thereof in the short direction is narrower than a width w₂ of the tab wiring 40. In this case, the arrangement, where the tab wiring 40 is displaced by Δy in the short direction, reduces the area where the tab wiring 40 and the adhesive 40 are in contact with each other. This may not reliably bond the tab wiring 40.

FIG. 14B shows an adhesive 80 according to a second comparative example. The adhesive 80 according to the second comparative example extends linearly in the longitudinal direction and is provided such that a width w_{b} thereof in the short direction is thicker than the width w₂ of the tab wiring 40. In this manner, making thicker the width w_{b} where the adhesive 80 is provided allows the tab wiring 40 to be reliably bonded in the event that the tab wiring 40 is arranged in a position displaced in the short direction. However, increasing the width w_{b} of the adhesive 80 increases the area of the light-receiving surface 12 blocked by the adhesive 80; this lowers the power generation efficiency.

FIG. 14C shows an adhesive 80 according to the present embodiment. The adhesive 80 according to the present embodiment extends nonlinearly in the longitudinal direction. The adhesive 80 is provided such that the width wₐ where the adhesive 80 is applied is narrower than the width w₂ of the tab wiring 40 and such that the width w_{b} of the adhesive 80 in the short direction is thicker than the width w₂ of the tab wiring 40. Arranging the adhesive 80 in a nonlinear shape continuously in the short direction between upper vertices and lower vertices can prevent a reduction of the area, where the tab wiring 40 and the adhesive 80 are brought into contact with each other, in the event that the tab wiring 40 is arranged in a position displaced in the short direction. Since the adhesive 80 is provided such that the width wₐ where the adhesive 80 is applied is narrow, the area of the light-receiving surface 12 blocked by the adhesive 80 can be reduced as compared with the case where the thick adhesive 80 is applied linearly. This allows the tab wiring 40 to be reliably bonded while the solar cell module 100 according to the present embodiment suppresses a drop in the power generation efficiency. In addition, the detachment or separation of the tab wiring 40 can be prevented. As a result, the reliability of the solar cell module 100 can be enhanced.

In the solar cell module 100, the first fillets 52a and the second fillets 52b, which protrude in the short direction of the tab wiring 40, are provided in such a manner as be discontinuously provided on the light-receiving surface 12. Thus, a stress that acts on the solar cell element 70 resulting from provision of the resin portion can be reduced as compared with the case where the fillets bonding the light-receiving surface 12 to the tab wiring 40 are continuously provided in a region between the light-receiving surface 12 and the tab wiring 40. Similarly, in the solar cell module 100, the first fillets 54a and the second fillets 54b, which protrude in the short direction of the tab wiring 40, are provided in such a manner as be discontinuously provided on the back surface 14. Thus, a stress that acts on the back surface 14 can also be reduced as compared with the case where the fillets bonding the back surface 14 to the tab wiring 40 are continuously provided. Relieving and reducing the stresses acting on the solar cell element 70 prevents the detachment or separation of the tab wiring 40 and a damage to the solar cell element 70, so that the reliability of the solar cell module 100 can be enhanced.

The present invention has been described by referring to the embodiments and such description is for illustrative purposes only. It is understood by those skilled in the art that any arbitrary combinations of the constituting elements and processes could be developed as modifications and that such modifications are also within the scope of the present invention.

In the above-described embodiments, as shown in FIG. 12, the adhesive 80 is arranged in zigzags in accordance with the bus-bar electrode 34 extending in a zigzag shape. In a modification, the adhesive 80 may be arranged in a nonlinear shape or mode different from the zigzag shape of the bus-bar electrode 34.

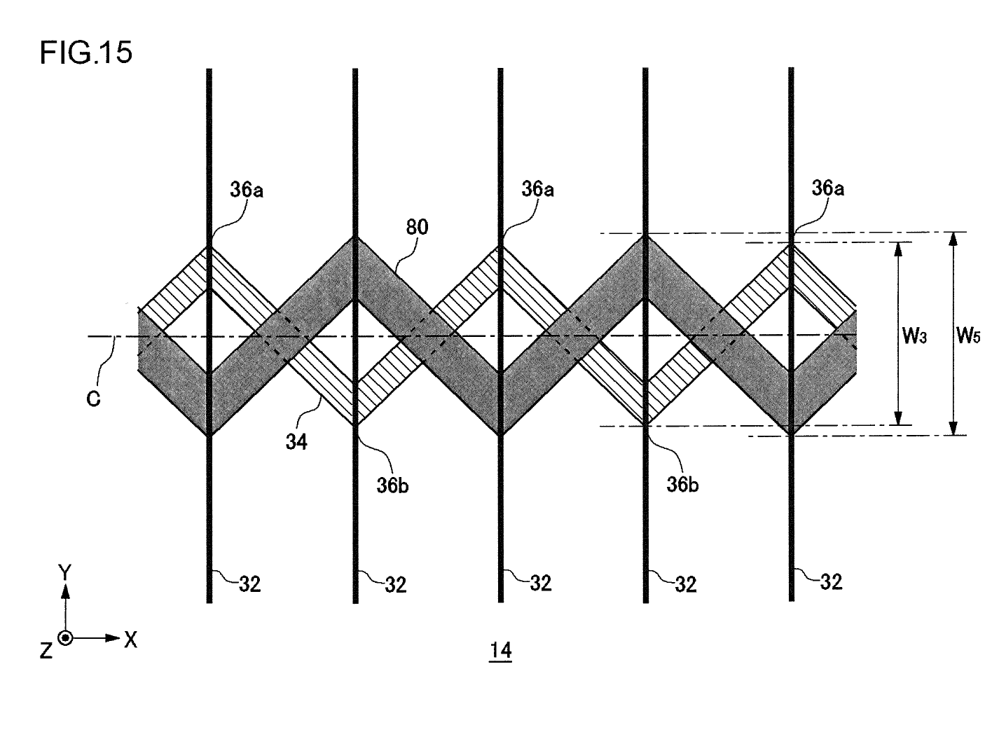

FIG. 15 is an external view of an adhesive 80 applied to a back surface 14 of a solar cell element according to a modification. In the back surface 14 thereof according to a modification, the adhesive 80 is applied in a zigzag shape such that a zigzag shape of the adhesive 80 and another zigzag shape of the bus-bar electrode 34 are formed alternately with each other in a criss-crossing manner. The adhesive 80 is so arranged as to avoid being placed on the first vertices 36a and the second vertices 36b of the bus-bar electrode 34. The adhesive 80 is arranged in a zigzag shape in the longitudinal direction such that the adhesive 80 protrudes in the negative y direction at a position of the finger electrode 32 where the first vertex 36a is provided. Also, the adhesive 80 is arranged such that the adhesive 80 protrudes in the positive y direction at a position of the finger electrode 32 where the second vertex 36b is provided. In order to arrange the adhesive 80 like this, the adhesive 80 may preferably be printed by shifting the printing plate 82 shown in FIG. 10 in the longitudinal direction by a half-cycle of the zigzag as compared with the embodiment. In the solar cell modules according to the modifications, too, similar advantageous effects to those of the above-described embodiments can be achieved.

In the above-described embodiments and modifications, the cycle of the zigzag of the bus-bar electrode 34 and the that of the adhesive 80 arranged on the back surface 14 are set such that both of the cycles are equal to each other. In a modification, these cycles may be set differently. Changing the cycle of the zigzag of the bus-bar electrode 34 from that of the adhesive 80 and vice versa allows a position where a stress that acts on the solar cell element 70 resulting from provision of the bus-bar electrode 34 as well as a position where a stress that acts thereon resulting from provision of the resin portion 54 to be dispersed or decentralized. As a result, the stresses can be relaxed and reduced.

In the above-described embodiments and modifications, an exemplary case is shown where the resin portion 54 is provided such that the width of the resin portion 54 on the back surface 14 in the short direction is wider than that of the bus-bar electrode 34 in the short direction. In a modification, the resin portion 54 may be provided such that the both widths are set equal to each other. Also, the resin portion 54 may be provided such that the width of the resin portion 54 in the short direction is narrower than that of the bus-bar electrode 34 in the short direction. Also, the resin portion 54 may be provided as follows. That is, either one or both of the widths vary such that, for example, the width of the resin portion 54 in the short direction is wider or narrower, depending on the position of the tab wiring 40 in the long direction, than that of the bus-bar electrode 34 in the short direction.

In the above-described embodiments and modifications, the bus-bar electrodes are provided on the light-receiving surface 12 and the back surface 14, and the bus-bar electrodes and the tab wirings 40 are brought into direct contact with each other so as to electrically conduct to each other. In a modification, the configuration and arrangement may be as follows. That is, no bus-bar electrodes provided in the light-receiving surface 12 and the back surface 14, the tab wirings 40 are bonded to the light-receiving surface 12 and the back surface 14 such that the finger electrodes and the tab wirings 40 are brought into direct contact with each other, and thereby the tab wirings 40 and the finger electrodes electrically conduct to each other. Note that either one of the light-receiving surface 12 and the back surface 14 may be configured such that no bus-bar electrode is provided on either one of them, and the tab wiring 40 may be bonded to a surface such that the finger electrodes and the tab wiring 40 are in direction contact with each other on the surface where no bus-bar electrode is provided.

In the above-described embodiments, an exemplary case is shown where a linearly-shaped bus-bar electrode 24 is provided on the light-receiving surface 12, and a bus-bar electrode 34 having a zigzag shape is provided on the back surface 14. However, it does not matter whether the bus-bar electrode provided on either one of the surfaces (the light-receiving surface 12 and the back surface 14) is of a linear shape or a zigzag shape. For example, the bus-bar electrodes on both the light-receiving surface 12 and the back surface 14 may be linearly-shaped bus-bar electrodes or may be those of zigzag shapes. Also, a bus-bar electrode 24 having a zigzag shape is provided on the light-receiving surface 12, and a linearly-shaped bus-bar electrode 34 is provided on the back surface 14, which is the opposite arrangement to the embodiment. Also, the configuration may be such that no bus-bar electrode is provided on either one of the light-receiving surface 12 and the back surface 14 or such that no bus-bar electrode is provided at all on the both of them.

In the above-described embodiments, an exemplary case is shown where the bus-bar electrode having a zigzag shape is provided on the back surface 14. In a modification, the bus-bar electrode may be one extending in a wavy line (wave-like shape) instead of the bus-bar electrode extending in a zigzag shape. In the bus-bar electrode extending in a wave-like shape, the shape thereof may be one where a sinusoidal waveform extends, for instance, and the extending direction of the electrode may be varied such that the vertex 36 is rounded.

In the above-described embodiments, an exemplary case is shown where the resin portion is formed in a zigzag shape as a resin portion extending in a nonlinear shape. In a modification, the resin portion may be one extending in a wavy line (wave-like shape) instead of the resin portion extending in a zigzag shape. In the resin portion extending in a wave-like shape, the shape thereof may be one where a sinusoidal waveform extends, for instance, and the extending direction of the resin portion may be varied such that the vertices thereof are rounded.

In the above-described embodiments, the tab wiring 40 is provided such that the tab wiring 40 extends in the x direction perpendicular to the y direction where the finger electrode extends. In a modification, the tab wiring 40 may be provided such that the tab wiring 40 extends in an oblique direction that intersects with both the x direction and the y direction along the light-receiving surface 12 or the back surface 14.

In the above-described embodiments, the tab wiring 40 is configured by the undersurface, bonded to the light-receiving surface 12, and the top surface facing the undersurface, which are both flat surfaces. In a modification, an asperity structure having asperities, a corrugated surface or the like may be formed on the top surface of the tab wiring 40; light incident on the top surface of the tab wiring 40 among the light incident toward the light-receiving surface may be scattered and then the light is diffused to a region where no tab wiring 40 is provided. Also, the asperity structure may be provided on the undersurface and the lateral surface of the tab wiring 40 instead of on the top surface thereof. Or the asperity structure may be provided on a plurality of surfaces among the top surface, undersurface and lateral surface.

### DESCRIPTION OF THE REFERENCE NUMERALS

10 Power generation layer
12 Light-receiving surface
14 Back surface
22 Finger electrode
24 Bus-bar electrode
32 Finger electrode
34 Bus-bar electrode
40 Tab wiring
40a Undersurface
40b Lateral surface
52 Resin portion
52a First fillet
52b Second fillet
54 Resin portion
54a First fillet
54b Second fillet
62 Protective substrate
64 Back sheet
66 Sealing layer
70 Solar cell element
80 Adhesive
100 Solar cell module

### INDUSTRIAL APPLICABILITY

The present invention can enhance the reliability of a solar cell module.

1. A solar cell module comprising:
a plurality of solar cell elements;
a tab wiring that connects the plurality of solar cell elements with each other; and
a resin portion that bonds the tab wiring and a surface of the solar cell element, the resin portion being provided, in a nonlinear shape, on the surface of the solar cell element.

2. The solar cell module according to claim 1, wherein the tab wiring extends in a predetermined direction along the surface thereof, and
wherein the resin portion overhangs from a short direction of the tab wiring.

3. The solar cell module according to claim 2, wherein the resin portion has a fillet that protrudes in a short direction of the tab wiring, and
wherein the fillets are provided such that the fillets are discontinuously provided in a longitudinal direction of the tab wiring.

4. The solar cell module according to claim 1,
wherein the surface of the solar cell element has a nonlinearly-shaped bus-bar electrode, and wherein the bus-bar electrode is so provided as to pass through a plurality of vertices, which are separated away in a short direction, from a center position of the bus-bar electrode in the short direction thereof, and
wherein the resin portion is so provided as to pass through the plurality of vertices in accordance with a shape of the bus-bar electrode.

5. The solar cell module according to claim 1, wherein the surface of the solar cell element has a nonlinearly-shaped bus-bar electrode, and
wherein the bus-bar electrode is so provided as to pass through a plurality of vertices, which are separated away in a short direction, from a center position of the bus-bar electrodes in the short direction thereof, and
wherein the resin portion is so provided as to circumvent a neighborhood of the vertices.

6. (canceled)
